(19) United States
(12) Patent Application Publication
(10) Pub. No.: US 2026/0068513 A1
(43) Pub. Date: Mar. 5, 2026

(54) METHOD OF PRODUCING ORGANIC LIGHT EMITTING ELEMENT, ORGANIC LIGHT EMITTING ELEMENT, AND DISPLAY DEVICE

(71) Applicant: CANON KABUSHIKI KAISHA, Tokyo (JP)

(72) Inventor: HIDEAKI TAKAHASHI, Kanagawa (JP)

(21) Appl. No.: 19/313,369

(22) Filed: Aug. 28, 2025

(30) Foreign Application Priority Data
Aug. 28, 2024 (JP) 2024-146854
Jul. 30, 2025 (JP) 2025-127485

(51) Int. Cl. H10K 71/13; H10K 50/11; H10K 102/00

(52) U.S. Cl. CPC H10K 71/13; H10K 50/11; H10K 2102/351

(57) ABSTRACT

Provided is a method of producing an organic light emitting element having a laminate structure in which a first electrode, a first organic compound layer, an intermediate layer, a second organic compound layer, and a second electrode are laminated in this order. The method includes forming the first organic compound layer, applying a liquid composition onto the first organic compound layer to form the intermediate layer having an average thickness of 3 nm or greater and 30 nm or less, and forming the second organic compound layer on the intermediate layer. Any of the first organic compound layer and the second organic compound layer includes a light emitting layer. The liquid composition contains a metal alkoxide having a tri- or higher valent metal atom and a solvent.

### BACKGROUND

### Field of the Technology

The present disclosure relates to a method of producing an organic light emitting element, an organic light emitting element, and a display device.

### Description of the Related Art

An organic light emitting element is an electronic element including a pair of electrodes composed of a first electrode and a second electrode, and an organic compound layer disposed between this pair of electrodes. A light emitting organic compound in the organic compound layer can be activated from a ground state to an excited state by injecting electrons and holes to the organic compound layer respectively from the pair of electrodes. Further, excess energy can be released as light when the organic compound in the excited state is returned to the ground state.

The organic light emitting element is also referred to as an organic electroluminescence element or an organic EL element. The organic light emitting element can usually be produced by a dry process such as a so-called vacuum deposition method, in which materials for forming various functional layers, such as an organic compound layer, an inorganic compound layer, and an electrode (layer), are heated and deposited on a substrate in a high vacuum. Materials can be difficult to uniformly deposit on a large-area substrate and in considering the material utilization efficiency, the production cost, and the like, a method of producing an organic light emitting element by a wet process, such as a printing method, has also been examined in recent years.

Further, since it is necessary to precisely laminate a plurality of organic compound layers having different properties and physical properties in order to enhance the performance of the organic light emitting element, a technique of insolubilizing an organic compound layer has also been examined.

A method of insolubilizing an organic compound layer by applying a liquid composition that contains a conductive organic material containing a crosslinkable reactive group to a substrate and heating the liquid composition to promote a crosslinking reaction has been suggested as the technique of insolubilizing an organic compound layer (see Japanese Patent Laid-Open No. 2015-12105). Further, a method of forming a film formed of a material insoluble in an organic solvent between organic compound layers to suppress mixing of the organic compound layers adjacent to each other (see Japanese Patent Laid-Open Nos. 2005-129450 and 2006-302637).

Methods suggested in Japanese Patent Laid-Open Nos. 2015-12105, 2005-129450, and 2006-302637 and various properties of organic light emitting elements produced by these methods have been considered, and it has been found that the organic light emitting element produced by the method suggested in Japanese Patent Laid-Open No. 2015-12105 has a high driving voltage because the organic compound layer contains a crosslinkable reactive group that does not contribute to electrical conduction.

Further, where a dispersion liquid of a material (composite (PEDOT:PSS) of poly(3,4-ethylenedioxythiophene) and polystyrene sulfonic acid) is insoluble in an organic solvent that is used in the method suggested in Japanese Patent Laid-Open No. 2005-129450 is allowed to stand for several days, the solid content is precipitated. Therefore, it has been understood that the dispersion liquid is required to be continuously agitated during the production and variation is likely to occur between organic light emitting elements to be obtained, and as a result, there is a problem in terms of the productivity. Further, it has been found that the organic light emitting element produced by the method suggested in Japanese Patent Laid-Open No. 2006-302637 also has insufficient luminous efficiency because the organic compound layer is not necessarily sufficiently insolubilized.

### SUMMARY

The present disclosure provides a method of producing an organic light emitting element that enables efficient production of an organic light emitting element having a low driving voltage and excellent luminous efficiency. Further, the present disclosure also provides an organic light emitting element having a low driving voltage and excellent luminous efficiency, and a display device including the organic light emitting element.

That is, according to an aspect of the present disclosure, there is provided a method of producing an organic light emitting element having a laminate structure in which a first electrode, a first organic compound layer, an intermediate layer, a second organic compound layer, and a second electrode are laminated in this order, the method including: forming the first organic compound layer; applying a liquid composition onto the first organic compound layer to form the intermediate layer having an average thickness of 3 nm or greater and 30 nm or less; and forming the second organic compound layer on the intermediate layer, in which any of the first organic compound layer and the second organic compound layer includes a light emitting layer, and the liquid composition contains a metal alkoxide having a tri- or higher valent metal atom and a solvent.

Features of the present disclosure will become apparent from the following description of embodiments with reference to the attached drawings. The following description of embodiments is described by way of example.

### BRIEF DESCRIPTION OF THE DRAWINGS

FIG. 1A is a schematic cross-sectional view showing an example of a pixel constituting a display device of the present disclosure.

FIG. 1B is a schematic cross-sectional view showing an embodiment of the display device of the present disclosure.

FIG. 2 is a schematic view showing another embodiment of the display device of the present disclosure.

FIG. 3A is a schematic view showing an example of an image capturing device.

FIG. 3B is a schematic view showing an example of a portable device.

FIG. 4A is a schematic view showing still another embodiment of the display device of the present disclosure.

FIG. 4B is a schematic view showing even still another embodiment of the display device of the present disclosure.

FIG. 5A is a schematic view showing an example of a lighting device.

FIG. 5B is a schematic view showing an example of a moving body.

FIG. 6A is a schematic view showing an example of a wearable device.

FIG. 6B is a schematic view showing another example of a wearable device.

### DESCRIPTION OF THE EMBODIMENTS

Hereinafter, the present disclosure will be described in more detail with reference to preferred embodiments. The physical property values are values at a normal temperature (25° C.) unless otherwise specified. Further, “average thickness” denotes the average thickness of each layer (film) in a region that emits light when a voltage is applied to an organic light emitting element.

The present disclosure provides a method of producing an organic light emitting element that enables efficient production of the organic light emitting element having a low driving voltage and excellent luminous efficiency. Further, provided is an organic light emitting element having a low driving voltage and excellent luminous efficiency, and a display device including the organic light emitting element.

Various examinations on the method of efficiently producing an organic light emitting element having a low driving voltage and excellent luminous efficiency have been conducted. As a result, it has been found that the configuration described below is effective, and the present disclosure has been completed. That is, a method of producing an organic light emitting element of the present disclosure is a method of producing an organic light emitting element having a laminate structure in which a first electrode, a first organic compound layer, an intermediate layer, a second organic compound layer, and a second electrode are laminated in this order. The production method of the present disclosure includes forming the first organic compound layer, applying a predetermined liquid composition onto the first organic compound layer to form the intermediate layer having an average thickness of 3 nm or greater and 30 nm or less, and forming the second organic compound layer on the intermediate layer. The liquid composition contains a metal alkoxide having a tri- or higher valent metal atom and a solvent. Further, any of the first organic compound layer and the second organic compound layer includes a light emitting layer.

The metal alkoxide in the liquid composition to be applied onto the first organic compound layer is hydrolyzed and polycondensed in the presence of air and water contained in the solvent of the liquid composition, and is converted into a so-called metalloxane compound having a repeating structure of metal atoms and oxygen atoms. The metalloxane compound is a compound having a three-dimensional network structure in which tri- or higher valent metal atoms and oxygen atoms are alternately bonded to each other. The metalloxane compound may be formed of only tri- or higher valent metal atoms and oxygen atoms or may contain a functional group such as an alkyl group represented by Formula (1).

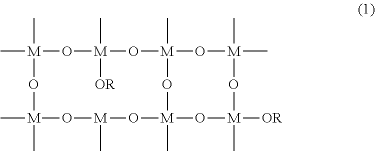

(In Formula (1), M represents a tri- or higher valent metal atom, and R represents an alkyl group.)

When the metal alkoxide having a tri- or higher valent metal atom is hydrolyzed and polycondensed, a dense three-dimensional network structure is formed as the molecular weight increases, and an intermediate layer that is poorly soluble in a solvent is formed.

Since the number of reaction sites of the polycondensation increases as the valence of the metal atom constituting the metal alkoxide increases, the poor solubility (solvent resistance) of the intermediate layer to be formed is improved. When the intermediate layer having an average thickness of 3 nm or greater is formed, the solvent resistance of the first organic compound layer is improved, and thus mixing of the first organic compound layer with the second organic compound layer, which is likely to occur during the formation of the second organic compound layer, can be suppressed.

As a result, the first organic compound layer and the second organic compound layer can be formed to be clearly separated from each other so that the functions of each layer can be sufficiently exhibited, and thus the luminous efficiency of an organic light emitting element to be obtained can be improved. Further, an organic light emitting element that can be driven at a low applied voltage equivalent to a case where an intermediate layer is not provided can be obtained by forming an intermediate layer having an average thickness of 30 nm or less.

Further, the liquid composition containing a metal alkoxide and a solvent is formed such that the solid content is unlikely to be precipitated as compared with a dispersion liquid of a polymer compound such as PEDOT:PSS, and thus can be stored in a uniform state for a long period of time. Therefore, in the production method of the present disclosure, the liquid composition for forming an intermediate layer is not required to be agitated. In addition, variation is unlikely to occur in properties and the like of the intermediate layer to be formed and the organic light emitting element to be obtained, and thus the productivity is excellent.

### Organic Light Emitting Element

The organic light emitting element of the present disclosure has a laminate structure in which constituent layers including a first electrode, a first organic compound layer, a second organic compound layer, and a second electrode are laminated. The constituent layers include an intermediate layer having an average thickness of 3 nm or greater and 30 nm or less, which is disposed between the first organic compound layer and the second organic compound layer. Any of the first organic compound layer and the second organic compound layer includes a light emitting layer. Further, the intermediate layer contains a metalloxane compound having a tri- or higher valent metal atom. Hereinafter, the organic light emitting element of the present disclosure will be described in detail.

### Configuration of Organic Light Emitting Element

The organic light emitting element has a laminate structure in which a plurality of constituent layers are laminated. The plurality of constituent layers include a first electrode, a first organic compound layer, a second organic compound layer, and a second electrode. The plurality of constituent layers further include an intermediate layer disposed between the first organic compound layer and the second organic compound layer. Specific examples of the laminate structure of the organic light emitting element include a structure in which a substrate, an insulating layer, a first electrode, a first organic compound layer, an intermediate layer, a second organic compound layer, and a second electrode are laminated in this order. The intermediate layer is disposed between and adjacent to the first organic compound layer and the second organic compound layer. A third organic compound layer may be provided between the second organic compound layer and the second electrode. A protective layer, a color filter, and the like may further be provided on the second electrode (in a direction opposite to the direction of the substrate). In a case where a color filter is provided, a planarizing layer may further be provided between the protective layer and the color filter.

### Substrate

A substrate formed of a material such as quartz, glass, silicon, a resin, a metal, or the like can be used as the substrate. Members, for example, a switching element such as a transistor, and a wiring are provided on the substrate, and an insulating layer can further be provided on these members. The insulating layer is a layer formed of a material capable of forming a contact hole that ensures electrical connection between an anode and a wiring and capable of ensuring insulation properties with a wiring that is not connected. Examples of the material forming such an insulating layer include a resin such as polyimide, and a silicon compound such as silicon oxide or silicon nitride.

### Electrode

A pair of electrodes is composed of a first electrode and a second electrode. One of the first electrode and the second electrode is an anode, and the other is a cathode. In a case where a voltage is applied in a direction in which the organic light emitting element emits light, the electrode with a high potential is an anode, and the other is a cathode. In other words, the electrode that supplies holes to the light emitting layer is an anode, and the electrode that supplies electrons is a cathode. Each electrode may be formed of one or two or more kinds of materials. Further, each electrode may be a single layer or a laminate in which two or more layers are laminated.

The anode can be formed of a material with a large work function. Examples of such a material include metals such as gold, platinum, silver, copper, nickel, palladium, cobalt, selenium, vanadium, and tungsten, metal oxides such as tin oxide, zinc oxide, indium oxide, indium tin oxide (ITO), and indium zinc oxide, mixtures and alloys thereof, and conductive polymers such as polyaniline, polypyrrole, and polythiophene.

As a material for forming an anode in a case of being used as a reflective electrode, a metal such as chromium, aluminum, silver, titanium, tungsten, or molybdenum, or an alloy or a laminate thereof can be used. Further, as a material for forming an anode in a case of being used as a transparent electrode, a metal oxide such as indium tin oxide (ITO) or an indium zinc oxide can be used. A photolithography technique can be used to form an anode.

A cathode can be formed of a material with a small work function. Examples of such a material include alkali metals such as lithium, alkaline earth metals such as calcium, other metals such as aluminum, titanium, manganese, silver, lead, and chromium, and oxides, mixtures, and alloys thereof. Examples of the alloys include magnesium-silver, aluminum-lithium, aluminum-magnesium, silver-copper, and zinc-silver. Examples of the oxides of metals include indium tin oxide (ITO). Among these, as the material for forming a cathode, silver and a silver alloy can be suitably used, and a silver alloy can be more suitably used from the viewpoint of suppressing aggregation of silver. The ratio of silver contained in the silver alloy to the other metal is not limited as long as the aggregation of silver can be suppressed. For example, the ratio of silver to the other metal may be about 1:1 at a mass ratio. A photolithography technique can be used to form a cathode.

A cathode may be formed of a metal oxide such as indium tin oxide (ITO) to use the organic light emitting element as a top-emission element, or a reflective electrode may be formed of a metal such as aluminum (Al) to use the organic light emitting element as a bottom-emission element. A photolithography technique or a sputtering method can be used to form a cathode. Between these methods, a cathode can be formed by a sputtering method (DC or AC). The cathode (film) formed by the sputtering method has an excellent coverage and can reduce the resistance.

### Protective Layer

A protective layer can be provided on the cathode (second electrode). Glass having a moisture absorbent layer adheres onto the cathode to provide a protective layer, and thus penetration of water or the like into the organic compound layer can be suppressed, and occurrence of display defects can be suppressed. Further, penetration of water or the like into the organic compound layer can be suppressed by providing a passivation film such as silicon nitride on the cathode as a protective layer. The protective layer can be formed by a chemical vapor deposition method (CVD method). Further, a protective layer having a two-layer structure may be provided by an atomic layer deposition method (ALD method) after the film formation using a chemical vapor deposition method. For example, after the formation of the cathode, the cathode is conveyed to another chamber while the vacuum is maintained, and a silicon nitride film can be formed as a protective layer using a CVD method. The protective layer can have an average thickness of 1 μm or greater and 10 μm or less.

### Color Filter

A color filter can be provided on the protective layer. A color filter having a size corresponding to the size of the organic light emitting element may be provided on a different substrate, and the substrate may be bonded to the substrate where the organic light emitting element is provided, or a color filter may be patterned by a photolithography technique. The color filter can be formed of a polymer material or the like.

### Planarizing Layer

A planarizing layer can be provided between the protective layer and the color filter. Examples of a constituent material of the planarizing layer include organic compounds. Among these, the planarizing layer can be formed of an organic compound of a polymer such as a resin. The planarizing layer may be provided above and below (both sides) the color filter, and the constituent materials of the planarizing layers may be the same as or different from each other. Examples of the constituent materials of the planarizing layers include resins such as a polyvinylcarbazole resin, a polycarbonate resin, a polyester resin, an ABS resin, an acrylic resin, a polyimide resin, a phenol resin, an epoxy resin, a silicon resin, and a urea resin.

### Counter Substrate

A counter substrate can be provided on the planarizing layer. The counter substrate is a substrate provided at a position facing the above-described substrate. Examples of the material for forming the counter substrate include the same materials as those for forming the above-described substrate.

### Organic Compound Layer

The organic compound layer includes a first organic compound layer and a second organic compound layer. Further, any of the first organic compound layer and the second organic compound layer includes a light emitting layer. Each of the first organic compound layer and the second organic compound layer may be a single layer or a laminate in which two or more layers are laminated.

In a case where the organic compound layer is a laminate having a plurality of layers, the organic compound layer includes layers other than the light emitting layer. Examples of the layers other than the light emitting layer include a hole injection layer, a hole transport layer, an electron blocking layer, a hole/exciton blocking layer, an electron transport layer, and an electron injection layer. The hole transport layer and the electron transport layer are also referred to as a charge transport layer. The light emitting layer may be a single layer or a laminate in which two or more layers are laminated.

The average thicknesses of the layers constituting the organic compound layer can each be independently 1 nm or greater and 10,000 nm or less (10 μm or less). From the viewpoint of further improving light emission properties, the average thicknesses of the layers constituting the organic compound layer can each be independently 10 nm or greater and 100 nm or less.

The average thickness of each layer (film) in the present specification is an average value of the thicknesses measured at any three or more sites using a stylus step profiler. As the stylus step profiler, for example, a commercially available device “P-16+” (trade name, manufactured by KLA-Tencor) can be used.

### Light Emitting Layer

As the material for forming the light emitting layer, a light emitting material, a host material, and a light emitting assist material can be used. Examples of the light emitting material include a fused ring compound such as a fluorene derivative, a naphthalene derivative, a pyrene derivative, a perylene derivative, a tetracene derivative, an anthracene derivative, or rubrene, and a polymer derivative such as a quinacridone derivative, a coumarin derivative, a stilbene derivative, an organic aluminum complex such as tris(8-quinolinolato)aluminum, an indium complex, a platinum complex, a rhenium complex, a copper complex, a europium complex, a ruthenium complex, a poly(phenylenevinylene) derivative, a poly(fluorene) derivative, or a poly(phenylene) derivative.

Examples of the host material and the light emitting assist material include an aromatic hydrocarbon compound, a derivative of an aromatic hydrocarbon compound, a carbazole derivative, a dibenzofuran derivative, a dibenzothiophene derivative, an organic aluminum complex such as tris(8-quinolinolato)aluminum, and an organic beryllium complex. The host material can have an anthracene skeleton, a tetracene skeleton, a perylene skeleton, a fluorene skeleton, or a pyrene skeleton in a molecular structure.

### Hole Injection Layer and Hole Transport Layer

As the materials for forming the hole injection layer and the hole transport layer, a hole injection transporting compound can be used. Examples of the hole injection transporting compound include a triarylamine derivative, an arylcarbazole derivative, a phenylenediamine derivative, a stilbene derivative, a phthalocyanine derivative, a porphyrin derivative, poly(vinylcarbazole), poly(thiophene), and other conductive polymers. These hole injection transporting materials are used as the materials for forming an electron blocking layer. Further, the hole injection layer and the hole transport layer may be individual layers or may be included in the same layer. Hereinafter, in a case where the hole injection layer and the hole transport layer are included in the same layer, the layers will be referred to as a hole injection transport layer.

### Electron Transport Layer

An electron transporting material can be used as the material for forming the electron transport layer. Examples of the electron transporting material include fused ring compounds such as a fluorene derivative, a naphthalene derivative, a chrysene derivative, and an anthracene derivative in addition to an oxadiazole derivative, an oxazole derivative, a pyrazine derivative, a triazole derivative, a triazine derivative, a quinoline derivative, a quinoxaline derivative, a phenanthroline derivative, and an organic aluminum complex. These electron transporting materials are also used as the materials for forming a hole blocking layer.

### Electron Injection Layer

An electron injecting material can be used as the material for forming the electron injection layer. The electron injecting material is selected in consideration of the balance and the like between ease of injecting electrons from the cathode and hole injection properties. Examples of the electron injecting material include a compound containing an alkali metal such as lithium fluoride, a lithium complex such as lithium quinolinol, a benzimidazolidene derivative, an imidazolidene derivative, a fulvalene derivative, and an acridine derivative. These organic compounds include an n-type dopant and a reducing dopant.

### Intermediate Layer

The intermediate layer is disposed between the first organic compound layer and the second organic compound layer. The intermediate layer contains a metalloxane compound containing a tri- or higher valent metal atom. Examples of the tri- or higher valent metal atom include tungsten, vanadium, niobium, molybdenum, tantalum, titanium, zirconium, hafnium, silicon, germanium, tin, tellurium, aluminum, gallium, indium, antimony, iron, lanthanum, praseodymium, neodymium, samarium, dysprosium, and ytterbium. Among these, a penta- or higher valent metal atom can be used. Further, tungsten, vanadium, niobium, molybdenum, and tantalum can be suitably used, and tungsten can be more suitably used as the metal atom. Further, the metalloxane compound has no crystal structure as the crystal structure of a metal oxide. This is because a covalent bond is formed between a metal atom and an oxygen atom of the metalloxane compound, whereas an ionic bond is formed between a metal atom and an oxygen atom of a metal oxide.

The average thickness of the intermediate layer is 3 nm or greater and 30 nm or less. From the viewpoint of further improving the luminous efficiency of the organic light emitting element and further decreasing the driving voltage, the average thickness of the intermediate layer can be 5 nm or greater and 20 nm or less. The intermediate layer can be formed adjacent to the light emitting layer.

### Applications of Organic Light Emitting Element

The organic light emitting element of the present disclosure can be used, for example, as a constituent member of a display device or a lighting device. In addition, the organic light emitting element of the present disclosure can also be used as an exposure light source of an electrophotographic image recording device, a backlight of a liquid crystal display device, a light emitting device having a white light source provided with a color filter, or the like.

### Method of Producing Organic Light Emitting Element

A method of producing the organic light emitting element of the present disclosure is a method of producing an organic light emitting element having a laminate structure in which constituent layers including a first electrode, a first organic compound layer, a second organic compound layer, and a second electrode are laminated. The production method of the present disclosure includes forming the first organic compound layer, applying a predetermined liquid composition onto the first organic compound layer to form an intermediate layer having an average thickness of 3 nm or greater and 30 nm or less, and forming the second organic compound layer on the intermediate layer. The liquid composition contains a metal alkoxide having a tri- or higher valent metal atom and a solvent. Further, any of the first organic compound layer and the second organic compound layer includes a light emitting layer. Hereinafter, the production method of the present disclosure will be described in detail.

### Forming First Organic Compound Layer

The production method of the present disclosure includes forming the first organic compound layer. Examples of a method of forming the first organic compound layer include a dry process and a wet process. Examples of the dry process include a vacuum deposition method, an ionization deposition method, a sputtering method, and a plasma method. The wet process is a method of applying a liquid composition for forming the first organic compound layer, which contains the constituent materials of the organic compound layer and a liquid medium, to a target site such as a base material. Examples of a method of applying the liquid composition include a coating method such as a spin coating method, a cast coating method, a gravure coating method, a bar coating method, a roll coating method, a wire bar coating method, a dip coating method, a spray coating method, or a capillary coating method, and a printing method such as a screen method, a flexographic printing method, an offset printing method, or an ink jet method. Among these, a vacuum deposition method, an ionization deposition method, a spray coating method, and an ink jet method can be suitably used, and an ink jet method can be more suitably used. An organic light emitting element with a larger area can be easily produced by employing these methods.

The first organic compound layer can be formed by performing the wet process to apply the liquid composition for forming the first organic compound to a target site and removing the liquid medium in the liquid composition by drying the liquid composition.

The conditions for drying the liquid composition can be appropriately set depending on the constituent material of the first organic compound layer, the type of the liquid medium, and the like. The liquid composition can be dried in an air atmosphere or an inert gas atmosphere such as nitrogen or argon. In a case where the liquid composition is dried by being heated, the heating temperature can be set to 100° C. or higher and 250° C. or lower, or 110° C. or higher and 200° C. or lower. The heating time can be set to 5 minutes or longer and 60 minutes or shorter. Further, the liquid composition may be dried at a normal pressure (1 atm) or under pressure (100 Pa to 0.1 MPa).

### Forming Intermediate Layer

The production method of the present disclosure includes applying the liquid composition for forming an intermediate layer, which contains a metal alkoxide containing a tri- or higher valent metal atom and a solvent, onto the first organic compound layer to form the intermediate layer. From the viewpoint of the luminous efficiency, the intermediate layer can be formed adjacent to the light emitting layer contained in any of the first organic compound layer and the second organic compound layer. Examples of a method of applying the liquid composition onto the first organic compound layer include a coating method such as a spin coating method, a cast coating method, a gravure coating method, a bar coating method, a roll coating method, a wire bar coating method, a dip coating method, a spray coating method, or a capillary coating method, and a printing method such as a screen method, a flexographic printing method, an offset printing method, or an ink jet method. Among these, a spray coating method or an ink jet method can be suitably used, and an ink jet method can be more suitably used. An organic light emitting element with a larger area can be easily produced by employing these methods.

In forming the intermediate layer, an intermediate layer having an average thickness of 3 nm or greater and 30 nm or less is formed. From the viewpoint of further improving the luminous efficiency and producing an organic light emitting element that can be driven at a lower applied voltage, an intermediate layer having an average thickness of 5 nm or greater and 20 nm or less can be formed. The average thickness of the intermediate layer to be formed can be controlled by adjusting, for example, the content of the metal alkoxide in the liquid composition and the amount of the liquid composition to be applied.

The liquid composition for forming an intermediate layer contains a metal alkoxide and a solvent. The content (% by mass) of the metal alkoxide in the liquid composition can be set to 0.01% by mass or greater and 1.00% by mass or less with respect to the total mass of the liquid composition.

Examples of the metal alkoxide include tungsten(VI) ethoxide, vanadium(V) oxytriethoxide, niobium(V) ethoxide, niobium(V) isopropoxide, molybdenum(V) ethoxide, tantalum(V) ethoxide, tungsten(V) ethoxide, titanium(IV) ethoxide, titanium(IV) n-propoxide, titanium(IV) isopropoxide, titanium(IV) butoxide, titanium(IV) tert-butoxide, zirconium(IV) ethoxide, zirconium(IV) n-propoxide, hafnium(IV) ethoxide, hafnium(IV) isopropoxide, tetraethoxysilane, tetrapropoxysilane, germanium(IV) ethoxide, germanium(IV) isopropoxide, tin(IV) isopropoxide, tellurium(IV) ethoxide, aluminum(III) ethoxide, gallium(III) ethoxide, gallium(III) isopropoxide, indium(III) isopropoxide, antimony(III) ethoxide, antimony(III) isopropoxide, iron(III) ethoxide, lanthanum(III) ethoxide, praseodymium(III) isopropoxide, neodymium(III) isopropoxide, samarium(III) isopropoxide, dysprosium(III) isopropoxide, and ytterbium(III) isopropoxide.

In a case where a metal alkoxide having a plurality of reaction sites of polycondensation per molecule is used, an intermediate layer that is less likely to dissolve in a solvent can be formed. Therefore, the valence of the metal atom contained in the metal alkoxide can be 5 or higher. Examples of the metal alkoxide containing a penta- or higher valent metal atom include tungsten(VI) ethoxide, vanadium(V) oxytriethoxide, niobium(V) ethoxide, niobium(V) isopropoxide, molybdenum(V) ethoxide, tantalum(V) ethoxide, and tungsten(V) ethoxide.

The solvent contained in the liquid composition for forming an intermediate layer is a component for adjusting various properties of the liquid composition, such as the viscosity and the surface tension. Examples of the solvent include water, alcohols such as methanol, ethanol, n-isopropanol, isopropanol, 1-butanol, and 2-butanol, aromatic hydrocarbon compounds such as toluene, o-xylene, p-xylene, mesitylene, chlorobenzene, o-dichlorobenzene, anisole, and phenylcyclohexane, alkyl halides such as dichloromethane and chloroform, ethers such as diethyl ether, dibutyl ether, tetrahydrofuran, 2-methyltetrahydrofuran, 1,4-dioxane, and diethylene glycol dimethyl ether, ketones such as dimethoxyethane, cyclopentanone, cyclohexanone, and methyl ethyl ketone, esters such as ethyl acetate, butyl acetate, and methyl benzoate, amide compounds such as dimethylformamide and dimethylacetamide, and cyclic amide compounds (lactams) such as N-methylpyrrolidone and dimethylimidazolidinone. From the viewpoint of further suppressing elution of the first organic compound layer, water and alcohols can be suitably used, and an alcohol having 3 or less carbon atoms can be more suitably used as the solvent. The solvent can be used alone or in combination of two or more kinds thereof.

After the liquid composition is applied onto the first organic compound layer, the liquid composition can be heated in an atmosphere containing moisture such as the air atmosphere. In this manner, hydrolysis of the metal alkoxide can proceed more rapidly. Further, after the liquid composition is applied onto the first organic compound layer, the liquid composition can be heated at 200° C. or higher and 300° C. or lower to form an intermediate layer. The polycondensation reaction of the metal alkoxide can proceed more sufficiently by heating the liquid composition. The heating time can be set to 5 minutes or longer and 60 minutes or shorter. Further, the solvent contained in the liquid composition for forming an intermediate layer can be volatilized by heating the liquid composition. When the solvent is volatilized, the amount of the solvent contained in the intermediate layer can be reduced, and thus the influence of the solvent on the formed intermediate layer can be suppressed. Further, the heating temperature can be set to be higher than the boiling point of the solvent contained in the liquid composition for forming an intermediate layer in order to facilitate volatilization of the solvent.

### Forming Second Organic Compound Layer

The production method of the present disclosure includes forming the second organic compound layer on the intermediate layer. That is, the method of forming the second organic compound layer is a wet process of applying a liquid composition for forming the second organic compound layer, which contains the constituent materials of the organic compound layer and a liquid medium, onto the intermediate layer. Examples of a method of applying the liquid composition include a coating method such as a spin coating method, a cast coating method, a gravure coating method, a bar coating method, a roll coating method, a wire bar coating method, a dip coating method, a spray coating method, or a capillary coating method, and a printing method such as a screen method, a flexographic printing method, an offset printing method, or an ink jet method. Among these, a spray coating method and an ink jet method can be suitably used, and an ink jet method can be more suitably used. An organic light emitting element with a larger area can be easily produced by employing these methods.

The second organic compound layer can be formed by applying the liquid composition onto the intermediate layer and removing the liquid medium in the liquid composition by drying the liquid composition. The conditions for drying the liquid composition can be appropriately set depending on the constituent material of the organic compound layer, the type of the liquid medium, and the like. The liquid composition can be dried in an air atmosphere or an inert gas atmosphere such as nitrogen or argon. In a case where the liquid composition is dried by being heated, the heating temperature can be set to 100° C. or higher and 250° C. or lower, or 110° C. or higher and 200° C. or lower. The heating time can be set to 5 minutes or longer and 60 minutes or shorter. Further, the liquid composition may be dried at a normal pressure (1 atm) or under pressure (100 Pa to 0.1 MPa).

### Display Device

The display device of the present disclosure is a device including a plurality of pixels, and at least one of the plurality of pixels includes the above-described organic light emitting element and a transistor connected to this organic light emitting element. Hereinafter, the display device of the present disclosure will be described in detail.

The display device includes an image input unit that inputs image information from an area CCD, a linear CCD, a memory card, or the like, and an information processing unit that processes the input image information.

The CCD is a charge-coupled device. The display device may be an image information processing device that displays the input image information on a display unit. Further, the display unit of an image capturing element, an ink jet recording device, or the like may have a touch panel function. Examples of a driving type for the touch panel function include an infrared type, an electrostatic capacity type, a resistive film type, and an electromagnetic induction type. The display device may be used in a display unit of a so-called composite type recording device.

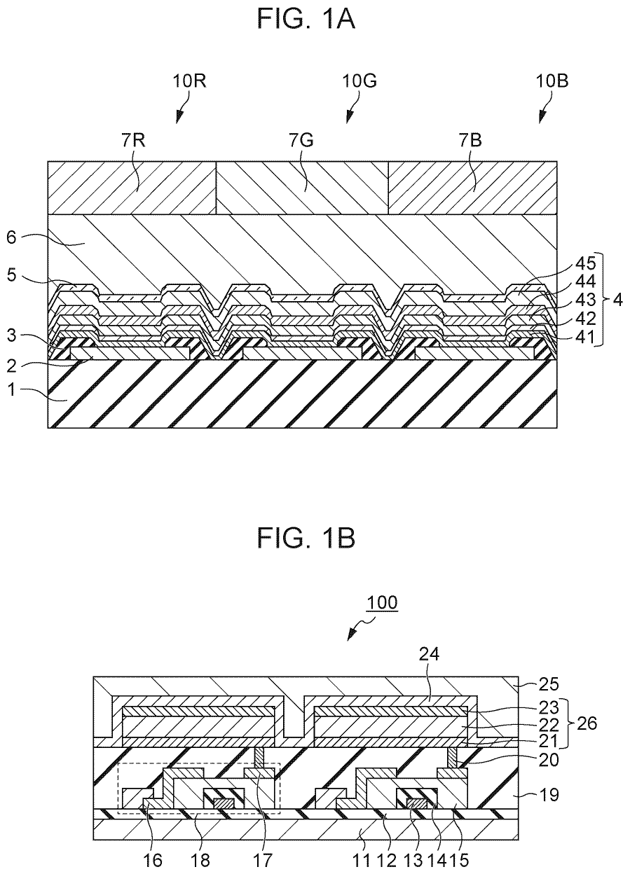

Next, the display device of the present disclosure will be described in detail with reference to the accompanying drawings. FIG. 1A is a schematic cross-sectional view showing an example of a pixel constituting the display device of the present disclosure. The pixel shown in FIG. 1A includes sub-pixels 10R, 10G, and 10B. The sub-pixels 10R, 10G, and 10B are divided according to the emission colors. The emission colors may be distinguished and determined by the wavelength of light emitted from the light emitting layer, or may be determined by selective transmission or color conversion of light emitted from the sub-pixels 10R, 10G, and 10B by color filters 7R, 7G, and 7B. Each of the sub-pixels 10R, 10G, and 10B includes an interlayer insulating layer 1, a reflective electrode 2 that is a first electrode provided on the interlayer insulating layer 1, an insulating layer 3 that covers an edge of the reflective electrode 2, and an organic semiconductor layer 4 that covers the first electrode and the insulating layer. Each of the sub-pixels 10R, 10G, and 10B further includes a transparent electrode 5, a protective layer 6, and the color filter 7R, 7G, or 7B.

A transistor and a capacitative element may be disposed on a layer below the interlayer insulating layer 1 or inside the interlayer insulating layer 1.

The transistor and the first electrode may be electrically connected through a contact hole or the like (not shown). The insulating layer 3 is also referred to as a bank or a pixel separation film. The insulating layer 3 covers the edge of the first electrode (reflective electrode 2) and is disposed to surround the first electrode. A portion of the first electrode where the insulating layer 3 is not disposed is connected to the organic semiconductor layer 4 and serves as a light emitting region. The organic semiconductor layer (organic compound layer) 4 includes a hole injection layer 41, a hole transport layer 42, an intermediate layer 43, a light emitting layer 44, and an electron transport layer 45. The second electrode may be any of a transparent electrode, a reflective electrode, and a semi-transmission electrode. The protective layer 6 is a layer for reducing permeation of a liquid component such as water into the organic compound layer. The protective layer may be formed of a plurality of layers. In a case where the protective layer is formed of a plurality of layers, the plurality of layers may include an inorganic compound layer and an organic compound layer.

The color filters 7R, 7G, and 7B are divided according to the colors. The color filters may be formed on a planarizing film (not shown). Further, a resin protective layer (not shown) may be disposed on the color filters. Further, the color filters may be formed on the protective layer 6, or may be provided on a counter substrate such as a glass substrate and bonded thereto.

FIG. 1B is a schematic cross-sectional view showing an embodiment of a display device of the present disclosure. A display device 100 shown in FIG. 1B includes an organic light emitting element 26 and an active element 18, such as a thin film transistor (TFT), connected to the organic light emitting element 26. The transistor, such as a TFT, is an example of the active element. The display device 100 includes a substrate 11 formed of a material such as glass or silicon, and an insulating layer 12 provided on the substrate 11. The active element 18, such as a TFT, is disposed on the insulating layer 12. The active element 18 includes a gate electrode 13, a gate insulating film 14, a semiconductor layer 15, a drain electrode 16, and a source electrode 17. An insulating film 19 is provided on an upper portion of the active electrode 18. An anode 21 constituting the organic light emitting element 26 and the source electrode 17 are connected through a contact hole 20 provided in the insulating film 19. Further, the electrical connection between the electrodes (the anode and the cathode) of the organic light emitting element and the electrodes (the source electrode and the drain electrode) of the active element is not limited to the mode shown in FIG. 1B. That is, the anode or the cathode may be electrically connected to the TFT source electrode or the drain electrode.

An organic semiconductor layer 22 formed of one layer is shown in the display device 100 shown in FIG. 1B, but the organic semiconductor layer may include a plurality of layers. A first protective layer 24 and a second protective layer 25 for reducing deterioration of the organic light emitting element 26 are provided on the cathode 23. For example, a transistor formed of a single crystal silicon wafer, a thin film transistor in which a device layer is provided on an insulating surface of a substrate, or the like can be used as the active element 18 constituting the display device 100. Examples of the active layer include non-single crystal silicon such as single crystal silicon, amorphous silicon, or microcrystalline silicon, and a non-single crystal oxide semiconductor such as an indium zinc oxide or an indium gallium zinc oxide.

The active element such as a transistor constituting the display device may be formed inside a substrate such as a silicon substrate. The expression “formed inside a substrate” denotes that a transistor is formed by processing a substrate such as a silicon substrate. That is, a substrate and a transistor may be integrally formed.

The emission luminance of the organic light emitting element is controlled by a TFT which is an example of the active element (switching element). When a plurality of organic light emitting elements are provided in a plane, an image can be displayed by the emission luminance of each of the plurality of organic light emitting elements. The switching element may be a TFT, a transistor formed of low-temperature polysilicon, or an active matrix driver formed on a substrate such as a silicon substrate. The organic light emitting element can be provided on a silicon substrate in a case where a display unit has, for example, a size of about 0.5 inches.

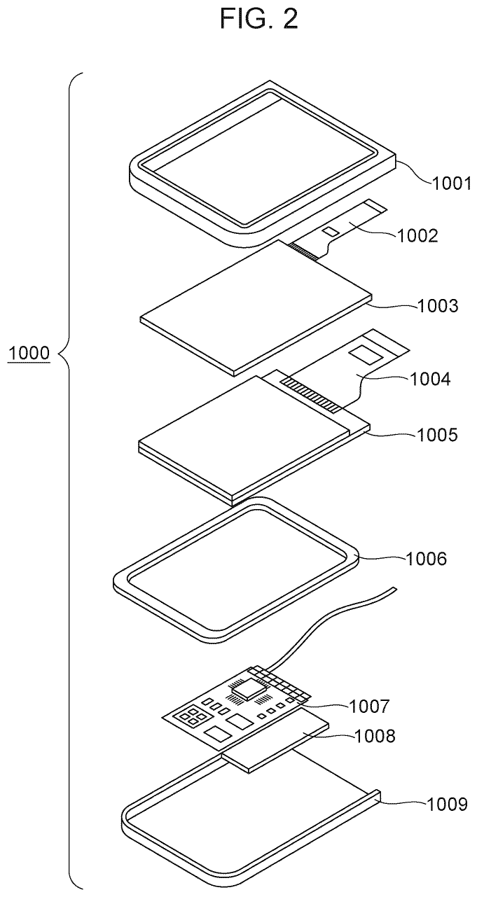

FIG. 2 is a schematic view showing another embodiment of the display device of the present disclosure. A display device 1000 shown in FIG. 2 includes an upper cover 1001 and a lower cover 1009 which are disposed to face each other. Further, the display device 1000 includes a touch panel 1003, a display panel 1005, a frame 1006, a circuit board 1007, and a battery 1008, which are disposed between the upper cover 1001 and the lower cover 1009. Flexible printed circuits (FPC) 1002 and 1004 are respectively connected to the touch panel 1003 and the display panel 1005. Transistors are printed on the circuit board 1007. In a case where the display device is a portable device, the battery 1008 is usually provided. In addition, the battery 1008 may be provided in a different position.

The display device may include color filters of a red color (R), a green color (G), and a blue color (B). The red, green, and blue color filters may be disposed in a delta array, a stripe array, or a mosaic array. The display device can be used as a display unit of a portable terminal. In a case where the display device is used as a display unit of a portable terminal, the display device may have a display function and an operation function. Examples of the portable terminal include mobile phones such as smart phones, tablets, and head-mounted displays.

The display device can be used as a display unit of an image capturing device including an optical unit that has a plurality of lenses and an image capturing element that receives light having passed through the optical unit. The image capturing device may include a display unit that displays information acquired by the image capturing element. Further, the display unit may be disposed in a state of being exposed to the outside of the image capturing device or in a state of being accommodated in a view finder. Examples of the image capturing device include digital cameras and digital video cameras. The image capturing device can also be referred to as a photoelectric conversion device.

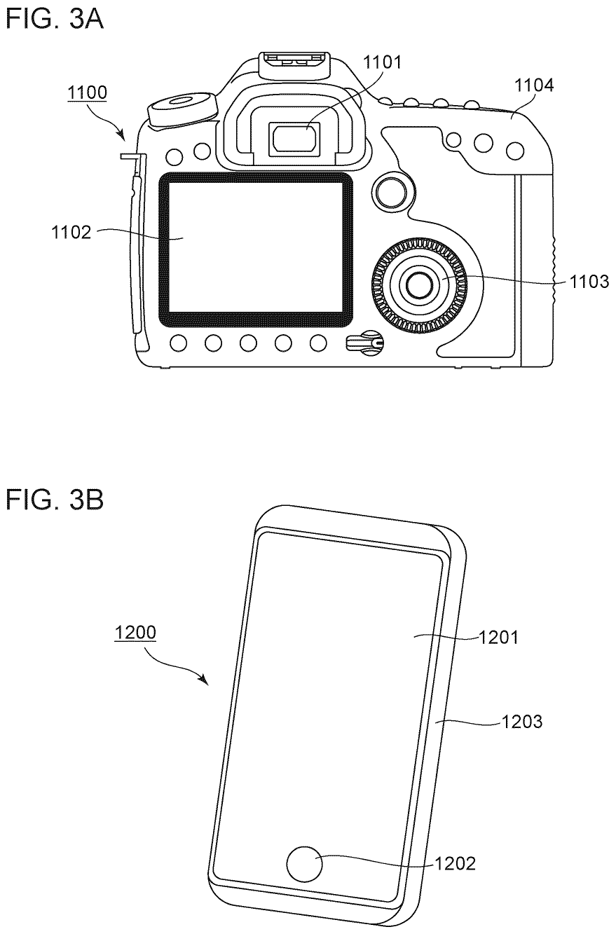

FIG. 3A is a schematic view showing an example of the image capturing device. An image capturing device 1100 shown in FIG. 3A includes a view finder 1101, a rear display 1102, an operation unit 1103, and a housing 1104. The display device can be used as the view finder 1101. The display device may display not only an image to be captured, but also environmental information, image capturing instruction, and the like. Examples of the environmental information include the intensity of external light, the orientation of external light, the movement speed of a subject, and the possibility that the subject is shielded by a shielding material.

Since the timing suitable for image capturing is only a short time, information is required to be displayed as quickly as possible. The organic light emitting element has a fast response speed, and thus can be suitably applied to a display device.

The image capturing device 1100 includes an optical unit (not shown). The optical unit has a plurality of lenses and forms an image on the image capturing element accommodated in the housing 1104. The focal point can be adjusted by controlling the relative positions of the plurality of lenses. The relative positions of the plurality of lenses can also be controlled by performing an automatic operation.

FIG. 3B is a schematic view showing an example of a portable device. A portable device 1200 shown in FIG. 3B includes a display unit 1201, an operation unit 1202, and a housing 1203. The organic light emitting element can be used in the display unit 1201. The housing 1203 includes a circuit, a printed board including the circuit, a battery, and a communication unit. The operation unit 1202 may be in the form of a button or may be a touch panel type reaction unit. The operation unit 1202 may be a biometric authentication unit that identifies fingerprints, performing unlocking, and the like. The portable device further including a communication unit can also be referred to as a communication device. The portable device 1200 may have a camera function by further including a lens and an image capturing element. An image captured by using the camera function is displayed on the display unit 1201. Examples of the portable device 1200 include a smartphone and a notebook computer.

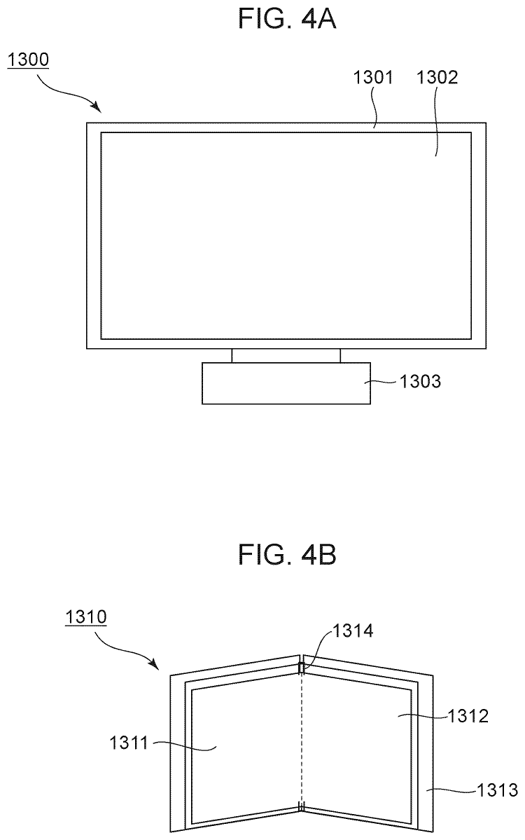

FIG. 4A is a schematic view showing still another embodiment of the display device of the present disclosure. A display device 1300 shown in FIG. 4A is a monitor of a television, a computer, or the like. The display device 1300 includes a frame 1301, a display unit 1302, and a base 1303 that supports the display unit 1302. The organic light emitting element can be used in the display unit 1302. The base 1303 is not limited to the form shown in FIG. 4A, and the lower side of the frame 1301 may also serve as the base. Further, the frame 1301 and the display unit 1302 may be curved. In a case where the frame 1301 and the display unit 1302 are curved, the curvature radius thereof can be 5000 mm or greater and 6000 mm or less.

FIG. 4B is a schematic view showing still another embodiment of the display device of the present disclosure. A display device 1310 shown in FIG. 4B is a so-called foldable display device that is formed to be foldable. The display device 1310 includes a first display unit 1311, a second display unit 1312, a housing 1313, and a bending point 1314. The organic light emitting element can be used in the first display unit 1311 and the second display unit 1312. The first display unit 1311 and the second display unit 1312 may be one seamless display unit. The first display unit 1311 and the second display unit 1312 can be divided at the bending point 1314. The first display unit 1311 and the second display unit 1312 may also display images different from each other or one image.

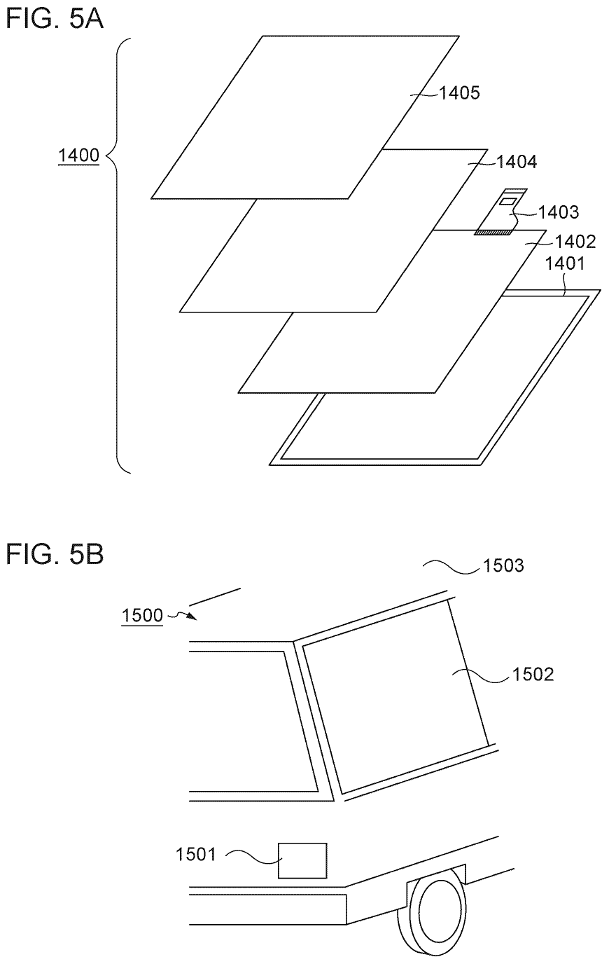

FIG. 5A is a schematic view showing an example of a lighting device. A lighting device 1400 shown in FIG. 5A includes a housing 1401, a light source 1402, a circuit board 1403, an optical film 1404, and a light diffusion unit 1405. The organic light emitting element can be used as the light source 1402. The optical film 1404 may be film that improves the color rendering properties of the light source. The light diffusion unit 1405 effectively diffuses light of the light source by lighting up or the like and thus can delivers the light to a wide range. The optical film and the light diffusion unit may be provided on a light emission side of the lighting device. A cover may be provided on the outermost portion as necessary.

The lighting device is, for example, a device that lights up a room and includes a light source and a member that transmits light emitted by the light source. The lighting device may emit light of any color from blue to red in addition to white or neutral white. The color “white” is a color having a color temperature of about 4,200K, and the color “neutral white” is a color having a color temperature of about 5,000K. The lighting device may further include a light control circuit that controls light. The lighting device may further include a power supply circuit connected to the organic light emitting element used as the light source. The power supply circuit is a circuit that converts an AC voltage to a DC voltage. The lighting device may further include a light diffusion unit and a color filter as a member that transmit light emitted by the light source. Further, the lighting device may further include a heat dissipation unit that releases heat inside the device to the outside of the device.

Examples of the material constituting the heat dissipation unit include a metal with high specific heat and liquid silicon.

FIG. 5B is a schematic view showing an example of a moving body. The moving body shown in FIG. 5B is an automobile 1500 including a lamp such as a tail lamp 1501 that is turned on when a braking operation or the like is performed. The organic light emitting element can be used as the tail lamp 1501. The tail lamp 1501 may include a protective member that protects the organic light emitting element. The protective member may be formed of a transparent material having a certain degree of high strength. Examples of such a material include a resin material such as a polycarbonate. The resin material such as a polycarbonate may contain a furandicarboxylic acid derivative, an acrylonitrile derivative, or the like.

The automobile 1500 may further include a car body 1503 and a window 1502 provided on the car body 1503. The window 1502 may be a transparent display formed of the organic light emitting element unless the window 1502 is used to confirm the front and rear of the automobile 1500. A member such as an electrode constituting the transparent display formed of the organic light emitting element is formed of a transparent material.

Examples of a moving body other than the automobile 1500 shown in FIG. 5B include a ship, an aircraft, and a drone. The moving body may include a machine body and a lamp that is provided on the machine body and emits light to inform of the position of the machine body. The organic light emitting element can be used as the lamp.

The display device can be applied to an image capturing display device, for example, a wearable device such as smart glasses, a head-mounted display, or a smart contact. Such an image capturing display device includes, for example, an image capturing device capable of photoelectrically converting visible light to an electric signal and a display device that emits visible light.

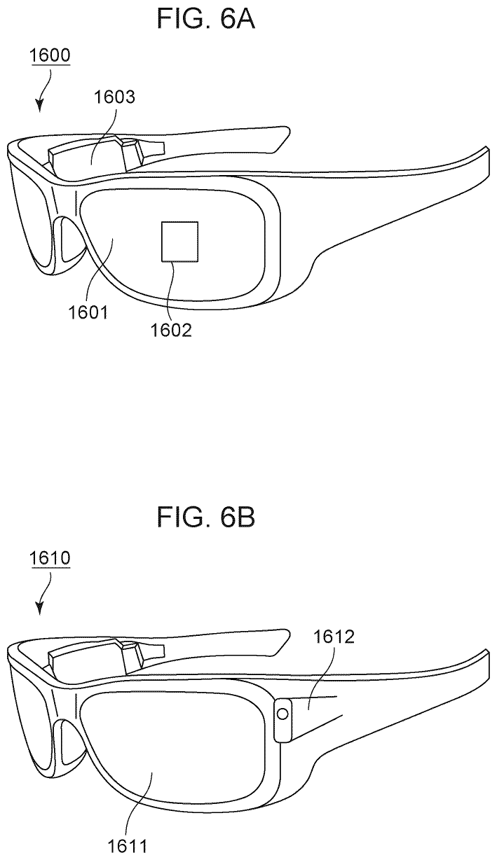

FIG. 6A is a schematic view showing an example of a wearable device. An image capturing device 1602 such as a CMOS sensor or a SPAD sensor is provided on a front surface side of a lens 1601 of smart glasses 1600 (glasses) shown in FIG. 6A. A complementary metal-oxide-semiconductor (CMOS) sensor is a solid-state image capturing element formed of a complementary metal-oxide-semiconductor. A single photon avalanche diode (SPAD) sensor is a sensor including an electronic element that outputs one large electric pulse signal by multiplication of one photon, like an avalanche, when the photon enters a pixel. The display device is provided on a rear surface side of the lens 1601. The smart glasses 1600 further include a control device 1603. The control device 1603 functions as a power supply that supplies power to the image capturing device 1602 and the display device and controls the operations of the image capturing device 1602 and the display device. An optical system for condensing light on the image capturing device 1602 is formed on the lens 1601.

FIG. 6B is a schematic view showing another example of the wearable device. Smart glasses 1610 (glasses) shown in FIG. 6B include a control device 1612. The control device 1612 is equipped with an image capturing device corresponding to the image capturing device 1602 (FIG. 6A) and a display device. A lens 1611 is formed with the image capturing device in the control device 1612 and an optical system for projecting light emitted from the display device, and an image is projected on the lens 1611. The control device 1612 functions as a power supply that supplies power to the image capturing device and the display device and controls the operations of the image capturing device and the display device. The control device may include a visual line detection unit that detects the visual line of a wearer. The visual line may be detected by using infrared rays. An infrared light emitting unit emits infrared light to the eyeballs of a user gazing at a display image. A captured image of the eyeballs can be obtained by detecting reflected light from the eyeballs to which infrared light has been emitted, using an image capturing unit including a light receiving element. Degradation of the image quality can be reduced by proving a reduction unit that reduces the amount of light from the infrared light emitting unit to the display unit in plan view.

The smart glasses 1610 detects the visual line of the user with respect to the display image from the captured image of the eyeballs obtained by capturing an image of infrared light. The detection of the visual line using the captured image of the eyeballs can be performed by employing any known method. As an example, a method of detecting the visual line based on a Purkinje image using reflection of irradiation light on the cornea can be used. Specifically, a visual line detection treatment is performed by a pupillary corneal reflection method. The visual line of the user is detected using a pupillary corneal reflection method by calculating a visual line vector representing the orientation (rotation angle) of the eyeballs based on the pupil image and the Purkinje image included in the captured image of the eyeballs.

The display device includes an image capturing device having a light receiving element and may control a display image of the display device based on visual line information of the user from the image capturing device. Specifically, the display device determines a first visual field region at which the user gazes and a second visual field region other than the first visual field region based on the visual line information. The first visual field region and the second visual field region may be determined by the control device of the display device, or an external control device determines any of the regions and the result may be received. In a display region of the display device, the display resolution of the first visual field region may be controlled to be higher than the display resolution of the second visual field region. That is, the resolution of the second visual field region may be set to be lower than the resolution of the first visual field region.

Further, the display region has a first display region and a second display region different from the first display region, and a region with a high priority is determined from the first display region and the second display region based on the visual line information. The first visual field region and the second visual field region may be determined by the control device of the display device, or an external control device determines any of the regions and the result may be received. The resolution of the region with a high priority may be controlled to be higher than the resolution of the region other than the region with a high priority. That is, the resolution of the region with a relatively lower priority may be decreased.

The first visual field region and the region with a higher priority may be determined by using artificial intelligence (AI). The AI may be a model formed to estimate the angle of the visual line from the image of the eyeballs and the distance from the eyeballs of the image to the object in front of the visual line, using the image of the eyeballs and the direction in which the eyeballs of the image are actually gazing as teaching data. The display device, the image capturing device, or an external device may have an AI program.

In a case where an external device has an AI program, the information is transmitted to the display device through communication. In a case where display is controlled based on visual line detection, this program can be suitably applied to smart glasses further including an image capturing device that captures an image of the outside. The smart glasses can display captured external information in real time.

As described above, information can be stably displayed with a satisfactory image quality for a long time by obtaining a display device including the organic light emitting element of the present disclosure. Both satisfactory visibility outdoors and power-saving display can be achieved by outputting light with high efficiency and high brightness.

According to the present disclosure, it is possible to provide a method of producing an organic light emitting element that enables efficient production of an organic light emitting element having a low driving voltage and excellent luminous efficiency. Further, according to the present disclosure, it is possible to provide an organic light emitting element having a low driving voltage and excellent luminous efficiency, and a display device including the organic light emitting element.

### EXAMPLES

Hereinafter, the present disclosure will be described in more detail with reference to examples and comparative examples, but the present disclosure is not limited to the following examples as long as the gist of the present disclosure is not exceeded. The amount of a component in units of “parts” and “%” is on a mass basis unless otherwise specified.

### Method of Measuring Thickness of Layer (Average Thickness)

The thickness of each layer (average thickness) formed was measured by measuring the thicknesses at any three sites of the film using a stylus step profiler (trade name “P-16+”, manufactured by KLA-Tencor) and determining the average value of the measured thicknesses.

### Production of Organic Light Emitting Element

### Example 1

An ITO film was formed on a glass substrate by a sputtering method to form an anode having a thickness of 100 nm, thereby obtaining a transparent conductive support substrate(ITO substrate). A solution was prepared by dissolving poly-TPD (Poly[N,N′-bis(4-butylphenyl)-N,N′-bis(phenyl)-benzidine]) in toluene. The ITO substrate that had been subjected to a UV ozone treatment was spin-coated with the prepared solution, and the solution was dried at 200° C. for 30 minutes, thereby forming a hole injection transport layer having an average thickness of 30 nm.

A liquid composition for forming an intermediate layer in which the concentration of tungsten(VI) ethoxide was 0.05% was prepared by dissolving tungsten(VI) ethoxide in ethanol. The hole injection transport layer was spin-coated with the liquid composition, and the composition was dried at 200° C. for 30 minutes, thereby forming an intermediate layer having an average thickness of 5 nm.

26DCzPPy (2,6-Bis(3-(9H-carbazol-9-yl)phenyl)pyridine) and Ir(mppy)₃ (Tris[2-(p-tolyl)pyridine]iridium (III)) were prepared. A solution in which a mixture obtained by mixing these at a mass ratio of 97:3 was dissolved in toluene was prepared. The intermediate layer was spin-coated with the solution, and the solution was dried at 110° C. for 15 minutes to form a light emitting layer having an average thickness of 35 nm, thereby obtaining a film sample. The obtained film sample was placed in a vacuum deposition machine, and an electron transport layer (TPBi) having an average thickness of 55 nm, an electron injection layer (LiF) having an average thickness of 0.5 nm, and a cathode (aluminum) having an average thickness of 100 nm were continuously formed by deposition. Next, a protective glass plate was placed thereon in a dry air atmosphere and sealed with an acrylic resin-based adhesive agent, thereby obtaining an organic light emitting element.

### Comparative Example 1

An organic light emitting element was produced in the same manner as in Example 1 except that the intermediate layer was not formed on the hole injection transport layer.

### Comparative Example 2

PEDOT:PSS (composite of poly(3,4-ethylenedioxythiophene) and polystyrene sulfonic acid, trade name “Clevios P AI 4083”, manufactured by Heraeus) was prepared. The prepared PEDOT:PSS was dissolved in water to prepare a liquid composition for forming an intermediate layer, in which the concentration of PEDOT:PSS was 1.00%. An organic light emitting element was produced in the same manner as in Example 1 except that the liquid composition prepared above was used.

### Examples 2 to 10 and Comparative Examples 3 to 6

Each organic light emitting element was produced in the same manner as in Example 1 except that the intermediate layer was formed under the conditions as listed in Table 1. The average thickness of the formed intermediate layer is listed in Table 1.

### Evaluation

Each of the following items of the produced organic light emitting elements was evaluated. In the present disclosure, “A” and “B” are considered as acceptable levels and “C” is considered as an unacceptable level in the evaluation criteria for each of the following items. The evaluation results thereof are listed in Table 1.

### External Quantum Efficiency and Driving Voltage

The external quantum efficiency and the driving voltage of each organic light emitting element produced under the condition of a current density of 10 mA/cm² were measured using a spectroradiometer (trade name “SR-LEDW-5N”, manufactured by Topcon Technohouse Corporation) and a DC voltage/current source (trade name “6253”, manufactured by ADC CORPORATION). Further, the external quantum efficiency and the driving voltage thereof were evaluated according to the following evaluation criteria.

### External Quantum Efficiency

A: The external quantum efficiency was 1.3 times or greater than the external quantum efficiency of Comparative Example 1.
B: The external quantum efficiency was 1.1 times or greater and less than 1.3 times the external quantum efficiency of Comparative Example 1.
C: The external quantum efficiency was less than 1.1 times the external quantum efficiency of Comparative Example 1.

### Driving Voltage

A: The driving voltage was less than 1.1 times the driving voltage of Comparative Example 1.
B: The driving voltage was 1.1 times or greater and less than 1.3 times the driving voltage of Comparative Example 1.
C: The driving voltage was 1.3 times or greater than the driving voltage of Comparative Example 1.

### Stability of Liquid Composition

Each liquid composition for forming an intermediate layer was allowed to stand at a normal temperature (25° C.) for 1 month. The state of the liquid composition after the standing was visually observed, and the stability thereof was evaluated according to the following evaluation criteria.
A: Precipitation of the solid content was not found.
C: Precipitation of the solid content was found.

TABLE 1
conditions for forming intermediate layer and evaluation results

| | | | | | Average | | | |
|---|---|---|---|---|---|---|---|---|
| | | | | | film thick- | | | |
| | Component | Concen- | Valence | Drying | ness of inter- | External | | Stability |
| | used in liquid | tration | of metal | temperature | mediate | quantum | Driving | of liquid |
| | composition | (%) | atom | (° C.) | layer (nm) | efficiency | voltage | composition |
| Example 1 | Tungsten(VI) | 0.05 | 6 | 200 | 5 | A | A | A |
| | ethoxide | | | | | | | |
| Example 2 | Tungsten(VI) | 0.10 | 6 | 200 | 10 | A | A | A |
| | ethoxide | | | | | | | |
| Example 3 | Tungsten(VI) | 0.20 | 6 | 200 | 20 | A | A | A |
| | ethoxide | | | | | | | |
| Example 4 | Tungsten(VI) | 0.10 | 6 | 200 | 10 | A | A | A |
| | ethoxide | | | | | | | |
| Example 5 | Molybdenum(V) | 0.10 | 5 | 200 | 10 | B | A | A |
| | ethoxide | | | | | | | |
| Example 6 | Titanium(IV) | 0.03 | 4 | 200 | 3 | B | A | A |
| | ethoxide | | | | | | | |
| Example 7 | Tungsten(VI) | 0.04 | 6 | 200 | 4 | B | A | A |
| | ethoxide | | | | | | | |
| Example 8 | Tungsten(VI) | 0.21 | 6 | 200 | 21 | A | B | A |
| | ethoxide | | | | | | | |
| Example 9 | Tungsten(VI) | 0.30 | 6 | 200 | 30 | A | B | A |
| | ethoxide | | | | | | | |
| Example 10 | Tungsten(VI) | 0.10 | 6 | 180 | 10 | B | A | A |
| | ethoxide | | | | | | | |
| Comparative | None | — | — | — | — | C | A | — |
| Example 1 | | | | | | | | |
| Comparative | PEDOT: PSS | 1.00 | — | 200 | 10 | A | A | C |
| Example 2 | | | | | | | | |
| Comparative | Tungsten(VI) | 0.02 | 6 | 200 | 2 | C | A | A |
| Example 3 | ethoxide | | | | | | | |
| Comparative | Molybdenum(VI) | 0.02 | 5 | 200 | 2 | C | A | A |
| Example 4 | ethoxide | | | | | | | |
| Comparative | Tungsten(VI) | 0.31 | 6 | 200 | 31 | A | C | A |
| Example 5 | ethoxide | | | | | | | |
| Comparative | Molybdenum(VI) | 0.31 | 5 | 200 | 31 | A | C | A |
| Example 6 | ethoxide | | | | | | | |

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-146854, filed Aug. 28, 2024 and Japanese Patent Application No. 2025-127485, filed Jul. 30, 2025, which are hereby incorporated by reference herein in their entirety.

What is claimed is:

1. A method of producing an organic light emitting element having a laminate structure in which a first electrode, a first organic compound layer, an intermediate layer, a second organic compound layer, and a second electrode are laminated in this order, the method comprising:
forming the first organic compound layer;
applying a liquid composition onto the first organic compound layer to form the intermediate layer having an average thickness of 3 nm or greater and 30 nm or less; and
forming the second organic compound layer on the intermediate layer,
wherein any of the first organic compound layer and the second organic compound layer includes a light emitting layer, and
the liquid composition contains a metal alkoxide having a tri- or higher valent metal atom and a solvent.

2. The method of producing an organic light emitting element according to claim 1,
wherein the metal atom is pentavalent or higher.

3. The method of producing an organic light emitting element according to claim 1,
wherein the intermediate layer having an average thickness of 5 nm or greater and 20 nm or less is formed.

4. The method of producing an organic light emitting element according to claim 1,
wherein the intermediate layer is formed by applying the liquid composition onto the first organic compound layer and heating the liquid composition at 200° C. or higher.

5. The method of producing an organic light emitting element according to claim 1,
wherein the intermediate layer is formed adjacent to the light emitting layer.

6. The method of producing an organic light emitting element according to claim 1,
wherein the metal atom is tungsten.

7. The method of producing an organic light emitting element according to claim 1,
wherein the solvent is an alcohol having 3 or less carbon atoms.

8. An organic light emitting element having a laminate structure in which a first electrode, a first organic compound layer, an intermediate layer, a second organic compound layer, and a second electrode are laminated in this order,
wherein the intermediate layer is a layer having an average thickness of 3 nm or greater and 30 nm or less, which is disposed between the first organic compound layer and the second organic compound layer,
any of the first organic compound layer and the second organic compound layer includes a light emitting layer, and
the intermediate layer contains a metalloxane compound having a tri- or higher valent metal atom.

9. A display device comprising:
a plurality of pixels,
wherein at least one of the plurality of pixels includes the organic light emitting element according to claim 8 and a transistor connected to the organic light emitting element.
